(19) United States
(12) Patent Application Publication
(10) Pub. No.: US 2026/0066009 A1
(43) Pub. Date: Mar. 5, 2026

(54) MEMORY DEVICE INCLUDING INTERNAL POWER GENERATING CIRCUIT AND METHOD OF SUPPLYING INTERNAL POWER THEREOF

(71) Applicant: Samsung Electronics Co., Ltd., Suwon-si (KR)

(72) Inventors: Sungho Moon, Suwon-si (KR); Hanseul Kim, Suwon-si (KR); Sang-Won Shim, Suwon-si (KR)

(21) Appl. No.: 19/244,075

(22) Filed: Jun. 20, 2025

(30) Foreign Application Priority Data
Aug. 27, 2024 (KR) 10-2024-0115176

(51) Int. Cl. G11C 16/30; G06F 3/06; G11C 16/04

(52) U.S. Cl. CPC G11C 16/30; G06F 3/0625; G06F 3/0655; G06F 3/0679; G11C 16/0483

(57) ABSTRACT

A memory device includes a plurality of internal circuits, and an internal power generating circuit electrically coupled to the plurality of internal circuits. The internal power generating circuit is configured to: (i) generate a standby reference voltage based on an external supply power signal, and supply a standby internal power signal generated in response to the standby reference voltage to the plurality of internal circuits during a standby mode, and (ii) generate a plurality of active reference voltages based on the external supply power signal, and supply each of a plurality of active internal power signals generated in response to respective ones of the plurality of active reference voltages to corresponding ones of the plurality of internal circuits during an active mode.

### REFERENCE TO PRIORITY APPLICATION

This application claims priority under 35 U.S.C. § 119 to Korean Patent Application No. 10-2024-0115176, filed Aug. 27, 2024, the disclosure of which is hereby incorporated herein by reference.

### BACKGROUND

Example embodiments of the present disclosure described herein relate to semiconductor memory devices and, more particularly, to memory devices having internal power generating circuits therein and methods of operating same.

An integrated circuit memory device is typically classified as a volatile memory or a non-volatile memory. As will be understood by those skilled in the art, the read and write speeds of a typical volatile memory, such as a DRAM or an SRAM, are fast, but the data stored therein disappear when power is turned off. In contrast, non-volatile memory may retain data even when the power is turned off. Thus, non-volatile memory devices may be used advantageously to store contents that must be preserved regardless of whether power is continuously maintained or not.

A representative example of a dominant non-volatile memory technology is flash memory; flash memory is widely used as a storage medium for audio and video data in information devices such as computers and smartphones. Recently, high-capacity, high-speed input/output and low-power technologies for the flash memory have been actively researched for installation in mobile devices such as the smartphone.

When a semiconductor memory is mounted in a mobile device, a technology of managing power consumption may be important. Accordingly, the semiconductor memory device may manage power by distinguishing an operating mode into a standby mode or an active mode. The semiconductor memory may be driven with a goal of using the minimum power during a standby mode, but may also be driven with a goal of implementing optimal performance during an active mode. However, in order to use the minimum power during the standby mode and achieve optimal performance when switching to the active mode, an appropriate technology of generating internal power is required.

### SUMMARY

Example embodiments of the present disclosure provide integrated circuit memory devices having reduced standby power requirements, by using one reference generation circuit during a standby mode, and individually or independently controlling internal power signals supplied to internal circuits using a plurality of reference generation circuits during an active mode, and methods supplying internal power thereto.

According to an example embodiment, a memory device includes: a plurality of internal circuits; and an internal power generating circuit generating at least one internal power based on an external supply power and supplying the at least one internal power to the plurality of internal circuits. The internal power generating circuit, during a standby mode, generates one standby reference voltage based on the external supply power and supplies a standby internal power generated based on the standby reference voltage to the plurality of internal circuits in common. The internal power generating circuit, during an active mode, generates a plurality of active reference voltages based on the external supply power and individually supplies a plurality of active internal power signals generated based on the plurality of active reference voltages to the plurality of internal circuits.

According to an example embodiment, a memory device includes: a first internal circuit; a second internal circuit; and an internal power generating circuit supplying a first internal power to the first internal circuit based on an external supply power and supplying a second internal power to the second internal circuit. The internal power generating circuit, during a standby mode, generates one standby reference voltage based on the external supply power, and supplies the first internal power and the second internal power, which are commonly set on the standby reference voltage, to the first internal circuit and the second internal circuit. The internal power generating circuit, during an active mode, generates a first active reference voltage and a second active reference voltage based on the external supply power, and supplies the first internal power set on the first active reference voltage to the first internal circuit, and supplies the second internal power set on the second active reference voltage to the second internal circuit.

According to another example embodiment, a memory device includes: a first internal circuit; a second internal circuit; and an internal power generating circuit supplying a first internal power to the first internal circuit based on an external supply power and supplying a second internal power to the second internal circuit. The internal power generating circuit includes: a main reference circuit generating one standby reference voltage based on a standby enable signal and generating a plurality of active reference voltages based on an active enable signal; a standby driver generating an internal standby voltage based on the standby reference voltage and supplying the internal standby voltage to the first internal circuit and the second internal circuit during a standby mode; a first active driver generating a first internal active voltage based on a first active reference voltage among the plurality of active reference voltages and supplying the first internal active voltage to the first internal circuit during an active mode; and a second active driver generating a second internal active voltage based on a second active reference voltage among the plurality of active reference voltages and supplying the second internal active voltage to the second internal circuit in the active mode.

According to another example embodiment, a memory device includes: a plurality of internal circuits; and an internal power generating circuit generating at least one internal power based on an external supply power and supplying the at least one internal power to the plurality of internal circuits. The internal power generating circuit, during a standby mode, generates one standby reference voltage based on the external supply power and supplies a standby internal power generated based on the standby reference voltage to the plurality of internal circuits in common. The internal power generating circuit, during an active mode, generates a plurality of active reference voltages based on the external supply power and individually supplies a plurality of active internal power signals generated based on the plurality of active reference voltages to the plurality of internal circuits.

According to an example embodiment, the internal power generating circuit includes a bandgap voltage reference circuit generating a bandgap reference voltage within a specified range regardless of changes in surrounding environment based on the external supply power.

According to an example embodiment, the internal power generating circuit includes: a standby reference circuit generating the standby reference voltage based on the bandgap reference voltage; and a plurality of standby drivers, which corresponds to each of the plurality of internal circuits, outputting a plurality of standby internal power signals set identically to the internal standby voltage based on the standby reference voltage.

According to an example embodiment, the plurality of standby internal power is supplied to the plurality of internal circuits regardless of the standby mode or the active mode, or is supplied to the plurality of internal circuits only in the standby mode.

According to an example embodiment, the internal power generating circuit includes: a plurality of active reference circuits generating a plurality of active reference voltages based on the bandgap reference voltage in the active mode; and a plurality of active drivers, which corresponds to each of the plurality of internal circuits, outputting a plurality of active internal power signals set to a plurality of internal active voltages based on the plurality of active reference voltages in the active mode.

### BRIEF DESCRIPTION OF THE FIGURES

The above and other objects and features of the present disclosure will become apparent by describing in detail embodiments thereof with reference to the accompanying diagrams.

FIG. 1 is a block diagram illustrating a storage device according to an example embodiment of the present disclosure.

FIG. 2 is a block diagram illustrating an operation of the internal power generating circuit of FIG. 1.

FIG. 3 is a block diagram illustrating an example embodiment of components included in the internal power generating circuit of FIG. 2.

FIG. 4 is a diagram illustrating an example embodiment of an operation of the internal power generating circuit of FIG. 3 during a standby mode.

FIG. 5 is a diagram illustrating an example embodiment of an operation of the internal power generating circuit of FIG. 3 during an active mode.

FIG. 6 is a diagram illustrating another example of an operation of the internal power generating circuit of FIG. 3 during a standby mode.

FIG. 7 is a diagram illustrating another example of an operation of the internal power generating circuit of FIG. 3 during an active mode.

FIG. 8 is a diagram illustrating another example of an operation of the internal power generating circuit of FIG. 3 during a standby mode.

FIG. 9 is a diagram illustrating another example of an operation of the internal power generating circuit of FIG. 3 during an active mode.

FIG. 10 is a diagram illustrating another example of an operation of the internal power generating circuit of FIG. 3 during a standby mode.

FIG. 11 is a diagram illustrating another example of an operation of the internal power generating circuit of FIG. 3 during an active mode.

FIG. 12 is a graph illustrating voltage levels of internal power signals output from the internal power generating circuit of FIG. 3 according to operation modes of the memory device of FIG. 2.

FIG. 13 is a block diagram illustrating another example of components included in the internal power generating circuit of FIG. 2.

FIG. 14 is a diagram illustrating an example embodiment of an operation of the internal power generating circuit of FIG. 13 during a standby mode.

FIG. 15 is a diagram illustrating an example embodiment of an operation of the internal power generating circuit of FIG. 13 during an active mode.

FIG. 16 is a diagram illustrating another example of an operation of the internal power generating circuit of FIG. 13 during a standby mode.

FIG. 17 is a diagram illustrating another example of an operation of the internal power generating circuit of FIG. 13 during an active mode.

FIG. 18 is a diagram illustrating another example of an operation of the internal power generating circuit of FIG. 13 during a standby mode.

FIG. 19 is a diagram illustrating another example of an operation of the internal power generating circuit of FIG. 13 during an active mode.

FIG. 20 is a block diagram illustrating an example embodiment of the memory device illustrated in FIG. 1.

FIG. 21 is a circuit diagram illustrating an example embodiment of a memory block BLK1 of the memory cell array described in FIG. 20.

FIG. 22 is a circuit diagram illustrating cell strings selected by a first string selection line SSL1 among cell strings of the memory block BLK1 illustrated in FIG. 21.

FIG. 23 is a diagram illustrating internal power supplied to the configurations of the memory device of FIG. 20 during a standby mode.

FIG. 24 is a diagram illustrating internal power supplied to components of the memory device during an active mode.

### DETAILED DESCRIPTION

Below, example embodiments of the present disclosure will be described in detail, and to such an extent that one of ordinary one can easily carry out the inventive concepts.

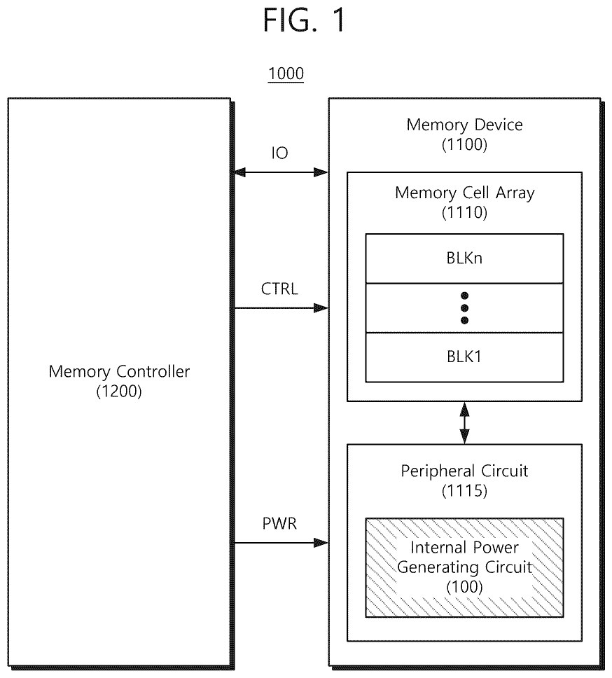

FIG. 1 is a block diagram illustrating a storage device according to an example embodiment of the present disclosure. Referring to FIG. 1, the storage device 1000 may include a memory device 1100 and a memory controller 1200. The storage device 1000 may store data in the memory device 1100 under control of the memory controller 1200. In addition, the storage device 1000 may output data stored in the memory device 1100 under the control of the memory controller 1200. The memory device 1100 may receive input/output signals 10 from the memory controller 1200 through input/output lines, receive control signals CTRL through control lines, and receive external supply power PWR through power lines. The memory device 1100 may include a memory cell array 1110 and a peripheral circuit 1115.

The memory cell array 1110 may have a plurality of memory blocks. Each of the plurality of memory blocks may have a planar 2D structure or a vertical 3D structure. Each of the plurality of memory blocks may include a plurality of memory cells. Single-bit data or multi-bit data may be stored in each memory cell. The memory cell array 1110 may be located (for example, disposed) next to or above the peripheral circuit 1115 in terms of the design layout structure. A structure in which the memory cell array 1110 is positioned over the peripheral circuit 1115 may be referred to as a cell on peripheral (COP) structure. As an example, the memory cell array 1110 may be manufactured as a chip separate from the peripheral circuit 1115. An upper chip including the memory cell array 1110 and a lower chip including the peripheral circuit 1115 may be connected to each other by a bonding method.

The peripheral circuit 1115 may include analog circuits and/or digital circuits required to store data in the memory cell array 1110 or read data stored in the memory cell array 1110. The peripheral circuit 1115 may receive commands, addresses, and/or data from the memory controller 1200 through input/output lines. The peripheral circuit 1115 may store data in the memory cell array 1110 according to the control signals CTRL. Alternatively or additionally, the peripheral circuit 1115 may read data stored in the memory cell array 1110 and provide the read data to the memory controller 1200 according to the control signals CTRL.

The peripheral circuit 1115 may include an internal power generating circuit 100 generating internal power signals of various levels based on the external supply power PWR. For example, the internal power generating circuit 100 may generate standby power and active power. The internal power generating circuit 100 may supply the standby power to each part of the memory device 1100 in a standby state. The internal power generating circuit 100 may supply the active power to each part of the memory device 1100 in an active state.

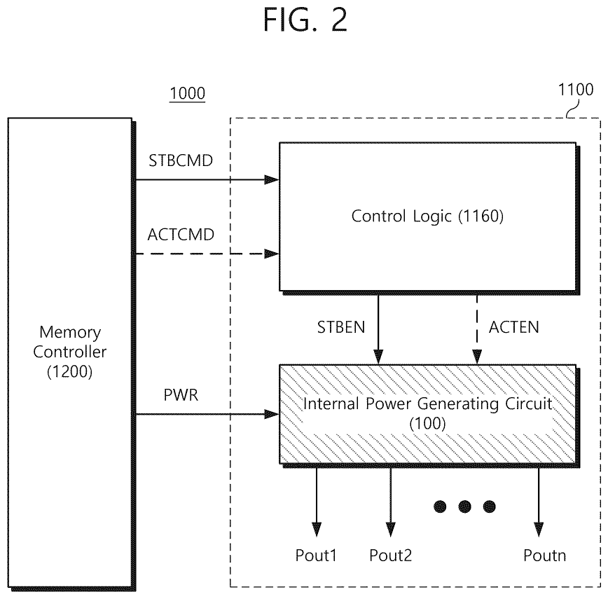

FIG. 2 is a block diagram illustrating an operation of the internal power generating circuit of FIG. 1. Referring to FIGS. 1 and 2, the memory device 1100 may operate during a standby mode or an active mode based on a command received from a memory controller 1200. The internal power generating circuit 100 may generate a plurality of internal power signals Pout1 to Poutn according to operation modes (for example, a standby mode or an active mode) of the memory device 1100.

In the standby mode, the control logic 1160 of the memory device 1100 may receive a standby command STBCMD from the memory controller 1200. The control logic 1160 may output a standby enable signal STBEN based on the standby command STBCMD. When receiving the standby enable signal STBEN, the internal power generating circuit 100 may output a plurality of internal power signals Pout1 to Poutn having a standby voltage based on an external supply power PWR. The plurality of internal power signals Pout1 to Poutn may be supplied to internal circuits (for example, control logic 1160 and an input/output circuit, etc.), which maintain a standby state in the standby mode. Moreover, the internal power generating circuit 100 may generate the plurality of internal power signals Pout1 to Poutn through one standby reference circuit. The plurality of internal power signals Pout1 to Poutn may be set to an identical standby voltage with low current and may be supplied to internal circuits set to maintain a standby state in the standby mode. Therefore, the internal power generating circuit 100 may use one standby reference circuit for the plurality of internal power signals Pout1 to Poutn and may reduce standby power compared to the case where a plurality of standby reference circuits are used in the standby mode.

In contrast, during the active mode, the control logic 1160 may receive an active command ACTCMD (for example, a read command or a write command) from the memory controller 1200. The control logic 1160 may output an active enable signal ACTEN based on the active command ACTCMD. When receiving the active enable signal ACTEN, the internal power generating circuit 100 may output the plurality of internal power signals Pout1 to Poutn having at least one active voltage based on the external supply power PWR. The plurality of internal power signals Pout1 to Poutn may be supplied to all internal circuits operating in the active mode. Moreover, the internal power generating circuit 100 may generate the plurality of internal power signals Pout1 to Poutn through corresponding ones of a plurality of active reference circuits. The plurality of internal power signals Pout1 to Poutn may be supplied to all internal circuits operating in the active mode, respectively. Therefore, the internal power generating circuit 100 may use a plurality of individual active reference circuits for the plurality of internal power signals Pout1 to Poutn. The internal power generating circuit 100 may individually or independently control the plurality of internal power signals Pout1 to Poutn supplied to internal circuits in the active mode.

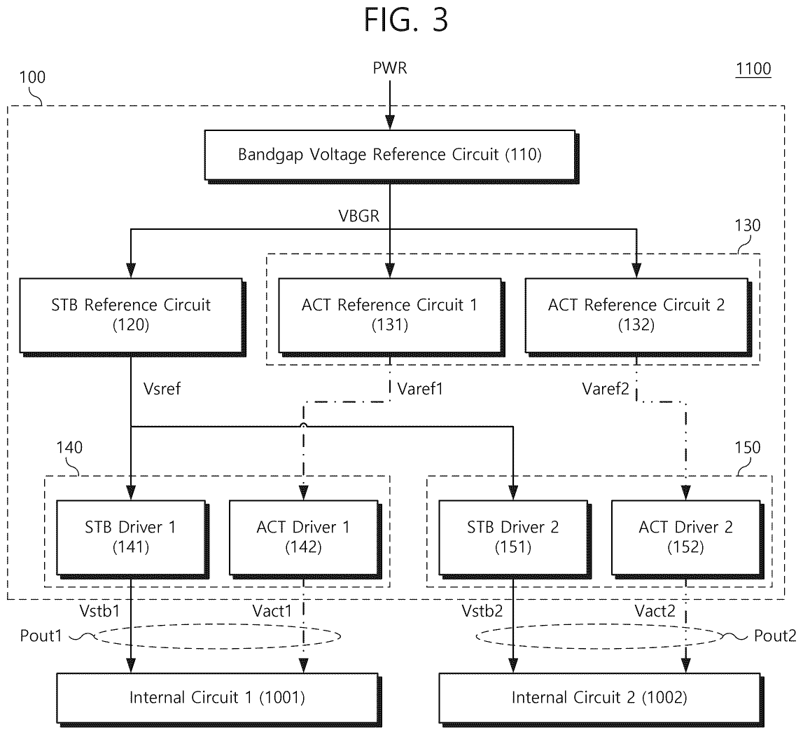

FIG. 3 is a block diagram illustrating an example embodiment of components included in the internal power generating circuit of FIG. 2. Referring to FIGS. 2 and 3, the internal power generating circuit 100 may generate a first internal power signal Pout1 and a second internal power signal Pout2, which are supplied to a first internal circuit 1001 and a second internal circuit 1002, respectively, in response to the received external supply power PWR signal. In FIG. 3, the first internal circuit 1001 and the second internal circuit 1002 are illustrated as examples, but the memory device 1100 may include a plurality of internal circuits (for example, control logic 1160, an input/output device, a memory cell array, a row decoder and/or a column decoder, etc.), and the internal power generating circuit 100 may output at least one internal power signal based on the number of the plurality of internal circuits.

The internal power generating circuit 100 may include a bandgap voltage reference circuit 110, a standby reference circuit 120, an active reference circuit 130, a first driver circuit 140 and/or a second driver circuit 150. The active reference circuit 130 may include a first active reference circuit 131 corresponding to the first internal circuit 1001 and a second active reference circuit 132 corresponding to the second internal circuit 1002. The first driver circuit 140 may include a first standby driver 141 and a first active driver 142 corresponding to the first internal circuit 1001. The second driver circuit 150 may include a second standby driver 151 and a second active driver 152 corresponding to the second internal circuit 1002.

The bandgap voltage reference circuit 110 may generate a highly stable bandgap reference voltage VBGR from the external power supply PWR voltage/signal. For example, the bandgap voltage reference circuit 110 may output a constant bandgap reference voltage VBGR, even in response to changes in PVT (Process, Voltage and/or Temperature). The bandgap reference voltage VBGR may be supplied equally to the standby reference circuit 120 and the active reference circuit 130, in some embodiments. In response, the standby reference circuit 120 may generate a standby reference voltage Vsref based on the bandgap reference voltage VBGR. As shown, the standby reference voltage Vsref may be commonly provided to the first standby driver 141 and the second standby driver 151.

As an example, the standby reference voltage Vsref may be provided to the first standby driver 141 and the second standby driver 151 both in the standby mode and in the active mode. As another example, the standby reference voltage Vsref may be provided to the first standby driver 141 and the second standby driver 151 in the standby mode, and may be blocked in the active mode. As another example (not illustrated), the internal power generating circuit 100 may include one standby driver. One standby driver may generate one internal standby voltage based on the standby reference voltage Vsref, and one internal standby voltage may be commonly provided to the first internal circuit 1001 and the second internal circuit 1002.

The first standby driver 141 may generate a first internal standby voltage Vstb1 based on the standby reference voltage Vsref. The first internal standby voltage Vstb1 may be provided to the first internal circuit 1001. The second standby driver 151 may generate a second internal standby voltage Vstb2 based on the standby reference voltage Vsref. The second internal standby voltage Vstb2 may be provided to the second internal circuit 1002. As an example, the first internal standby voltage Vstb1 and the second internal standby voltage Vstb2 may be equal to the standby reference voltage Vsref.

For example, the first standby driver 141 and the second standby driver 151 may be small drivers having relatively smaller operating current compared to the first active driver 142 and the second active driver 152. The first standby driver 141 and the second standby driver 151 may be relatively small drivers which provide only the minimum voltage necessary to maintain the standby state of the first internal circuit 1001 and the second internal circuit 1002 in the standby mode.

In contrast, during the active mode, the first active reference circuit 131 may generate a first active reference voltage Varef1 based on the bandgap reference voltage VBGR. The first active driver 142 may generate a first internal active voltage Vact1 based on the first active reference voltage Varef1. As an example, in the active mode, the first internal active voltage Vact1 may be combined with the first internal standby voltage Vstb1 and supplied to the first internal circuit 1001 as the first internal power signal Pout1. As another example, in the active mode, only the first internal active voltage Vact1 may be supplied to the first internal circuit 1001 as the first internal power signal Pout1.

In the active mode, the second active reference circuit 132 may generate a second active reference voltage Varef2 based on the bandgap reference voltage VBGR. The second active driver 152 may generate a second internal active voltage Vact2 based on the second active reference voltage Varef2. As an example, in the active mode, the second internal active voltage Vact2 may be combined with the second internal standby voltage Vstb2 and supplied to the second internal circuit 1002 as the second internal power signal Pout2. As another example, in the active mode, only the second internal active voltage Vact2 may be supplied to the second internal circuit 1002 as the second internal power signal Pout2.

As another example, the first active reference voltage Varef1 may be generated differently from the second active reference voltage Varef2. Similarly, the first internal active voltage Vact1 may be generated differently from the second internal active voltage Vact2. As a further example, the first active reference voltage Varef1 may be generated identically to the second active reference voltage Varef2. Similarly, the first internal active voltage Vact1 may be generated identically to the second internal active voltage Vact2.

The first active driver 142 and the second active driver 152 may be large drivers having relatively greater operating currents compared to the first standby driver 141 and the second standby driver 151. Accordingly, in the active mode, the first internal power signal Pout1 may have the first internal active voltage Vact1 regardless of a combination with the first internal standby voltage Vstb1. Likewise, in the active mode, the second internal power signal Pout2 may have the second internal active voltage Vact2 regardless of a combination with the second internal standby voltage Vstb2.

As described above, the internal power generating circuit 100 may generate one standby reference voltage Vsref for a plurality of standby power signals supplied to a plurality of internal circuits (for example, the first internal circuit 1001 and the second internal circuit 1002) through one standby reference circuit 120 in the standby mode. Accordingly, compared to a method of using a plurality of standby reference circuits corresponding to the plurality of internal circuits, the internal power generating circuit 100 may have a reduced area and may reduce current consumed for generating the standby reference voltage Vsref in the standby mode.

In addition, the internal power generating circuit 100 may include a plurality of active reference circuits (for example, a first active reference circuit 131 and a second active reference circuit 132) corresponding to a plurality of internal circuits (for example, a first internal circuit 1001 and a second internal circuit 1002) in the active mode. Accordingly, the internal power generating circuit 100 may individually or independently control a plurality of active power signals supplied to the plurality of internal circuits in the active mode.

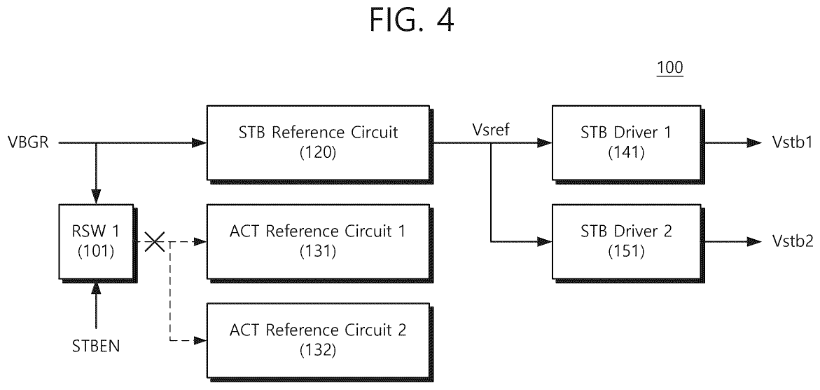

FIG. 4 is a diagram illustrating an example embodiment of an operation of the internal power generating circuit of FIG. 3 during a standby mode. Referring to FIGS. 3 and 4, the internal power generating circuit 100 may further include a first reference switch 101 which controls a flow of the bandgap reference voltage VBGR according to operation modes. The bandgap reference voltage VBGR output from the bandgap voltage reference circuit 110 of FIG. 3 may be commonly transmitted to the standby reference circuit 120 and the first reference switch 101.

The bandgap reference voltage VBGR may be commonly transmitted to the first active reference circuit 131 and the second active reference circuit 132 through the first reference switch 101. The first reference switch 101 may transmit or block the bandgap reference voltage VBGR based on a control signal (for example, a standby enable signal STBEN or an active enable signal ACTEN).

In the standby mode, the first reference switch 101 may block the bandgap reference voltage VBGR transmitted to the first active reference circuit 131 and the second active reference circuit 132 based on the standby enable signal STBEN, whereas the standby reference circuit 120 may output the standby reference voltage Vsref based on the bandgap reference voltage VBGR. The first standby driver 141 and the second standby driver 151 may commonly receive the standby reference voltage Vsref. The first standby driver 141 may output the first internal standby voltage Vstb1 based on the standby reference voltage Vsref. The second standby driver 151 may output the second internal standby voltage Vstb2 based on the standby reference voltage Vsref.

As an example, the first internal standby voltage Vstb1 and the second internal standby voltage Vstb2 may be set identically to the standby reference voltage Vsref. As another example, the first internal standby voltage Vstb1 and the second internal standby voltage Vstb2 may be set to be different from each other.

The first internal power signal Pout1 having the first internal standby voltage Vstb1 may be provided to the first internal circuit 1001. The second internal power signal Pout2 having the second internal standby voltage Vstb2 may be provided to the second internal circuit 1002. As described above, the internal power generating circuit 100 may generate internal power signals to be provided to the internal circuits in the standby mode through one standby reference circuit 120.

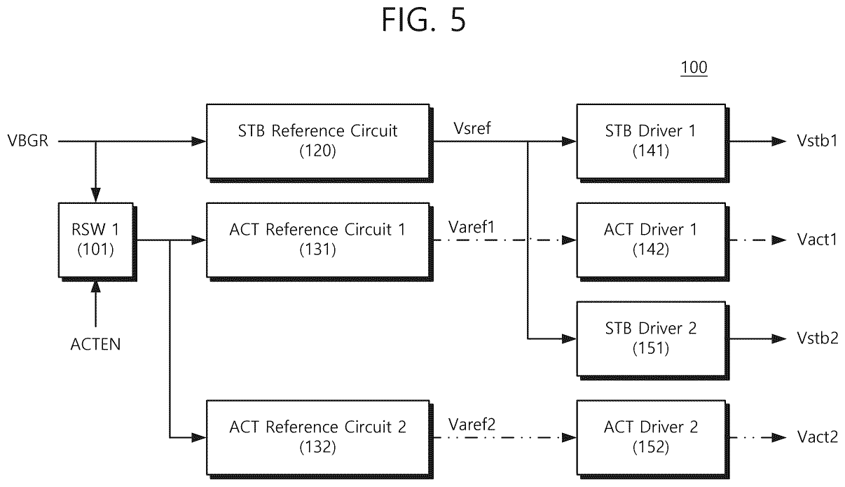

FIG. 5 is a diagram illustrating an example embodiment of an operation of the internal power generating circuit of FIG. 3 during an active mode. Referring to FIGS. 3 and 5, the internal power generating circuit 100 may further include a first reference switch 101 which controls a flow of the bandgap reference voltage VBGR according to operation modes. The bandgap reference voltage VBGR output from the bandgap voltage reference circuit 110 of FIG. 3 may be commonly transmitted to the standby reference circuit 120 and the first reference switch 101.

The bandgap reference voltage VBGR may be commonly transmitted to the first active reference circuit 131 and the second active reference circuit 132 through the first reference switch 101. The first reference switch 101 may transmit or block the bandgap reference voltage VBGR based on a control signal (for example, a standby enable signal STBEN or an active enable signal ACTEN). In the active mode, the first reference switch 101 may transmit the bandgap reference voltage VBGR to the first active reference circuit 131 and the second active reference circuit 132 based on the active enable signal ACTEN.

In the active mode, the first active reference circuit 131 may output the first active reference voltage Varef1 based on the bandgap reference voltage VBGR. The first active driver 142 may output the first internal active voltage Vact1 based on the first active reference voltage Varef1.

The second active reference circuit 132 may output the second active reference voltage Varef2 based on the bandgap reference voltage VBGR. The second active driver 152 may output the second internal active voltage Vact2 based on the second active reference voltage Varef2.

As an example, the first active reference voltage Varef1 may be set differently from the second active reference voltage Varef2. In addition, the first internal active voltage Vact1 may be set differently from the second internal active voltage Vact2. As another example, the first active reference voltage Varef1 may be set identically to the second active reference voltage Varef2. In addition, the first internal active voltage Vact1 may be set identically to the second internal active voltage Vact2.

Even in the active mode, the standby reference circuit 120 may output the standby reference voltage Vsref based on the bandgap reference voltage VBGR. The first standby driver 141 and the second standby driver 151 may commonly receive the standby reference voltage Vsref. The first standby driver 141 may output the first internal standby voltage Vstb1 based on the standby reference voltage Vsref. The second standby driver 151 may output the second internal standby voltage Vstb2 based on the standby reference voltage Vsref.

The first internal standby voltage Vstb1, the second internal standby voltage Vstb2, the first internal active voltage Vact1 or the second internal active voltage Vact2 may be set to be equal to or different from each other. As an example, the first internal standby voltage Vstb1 and the second internal standby voltage Vstb2 may be set identically to the standby reference voltage Vsref. As another example, the first internal standby voltage Vstb1 may be set to be different from the second internal standby voltage Vstb2.

As another example, one of the first internal active voltage Vact1 or the second internal active voltage Vact2 may be set to be equal to one of the first internal standby voltage Vstb1 or the second internal standby voltage Vstb2. As another example, the first internal standby voltage Vstb1, the second internal standby voltage Vstb2, the first internal active voltage Vact1 and/or the second internal active voltage Vact2 may all be set identically.

The first internal standby voltage Vstb1 and the first internal active voltage Vact1 may be integrated and provided to the first internal circuit 1001 as the first internal power signal Pout1. The second internal standby voltage Vstb2 and the second internal active voltage Vact2 may be integrated and provided to the second internal circuit 1002 as the second internal power signal Pout2. As described above, the internal power generating circuit 100 may generate internal power signals to be provided to internal circuits in the active mode through a plurality of active reference circuits.

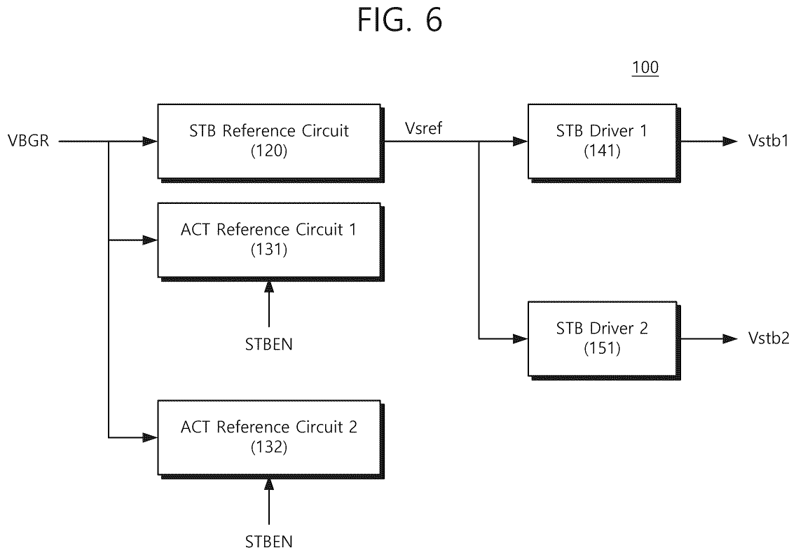

FIG. 6 is a diagram illustrating another example of an operation of the internal power generating circuit of FIG. 3 during a standby mode. Referring to FIGS. 3 and 6, in the standby mode, a standby enable signal STBEN output from the control logic 1160 of FIG. 2 may be input to the first active reference circuit 131 and the second active reference circuit 132. The bandgap reference voltage VBGR output from the bandgap voltage reference circuit 110 of FIG. 3 may be commonly supplied to the standby reference circuit 120, the first active reference circuit 131 and the second active reference circuit 132.

The first active reference circuit 131 and the second active reference circuit 132 may be activated or deactivated based on a control signal (for example, a standby enable signal STBEN or an active enable signal ACTEN). In the standby mode, when the standby enable signal STBEN is received, the first active reference circuit 131 and the second active reference circuit 132 may be deactivated and not output active reference voltages. In addition, in the standby mode, the standby reference circuit 120 may output the standby reference voltage Vsref based on the bandgap reference voltage VBGR. The first standby driver 141 and the second standby driver 151 may commonly receive the standby reference voltage Vsref.

The first standby driver 141 may output the first internal standby voltage Vstb1 based on the standby reference voltage Vsref. The second standby driver 151 may output the second internal standby voltage Vstb2 based on the standby reference voltage Vsref.

As an example, the first internal standby voltage Vstb1 and the second internal standby voltage Vstb2 may be set identically to the standby reference voltage Vsref. As another example, the first internal standby voltage Vstb1 and the second internal standby voltage Vstb2 may be set to be different from each other.

The first internal power signal Pout1 having the first internal standby voltage Vstb1 may be provided to the first internal circuit 1001. The second internal power signal Pout2 having the second internal standby voltage Vstb2 may be provided to the second internal circuit 1002. As described above, the internal power generating circuit 100 may generate internal power signals to be provided to internal circuits in the standby mode through one standby reference circuit 120.

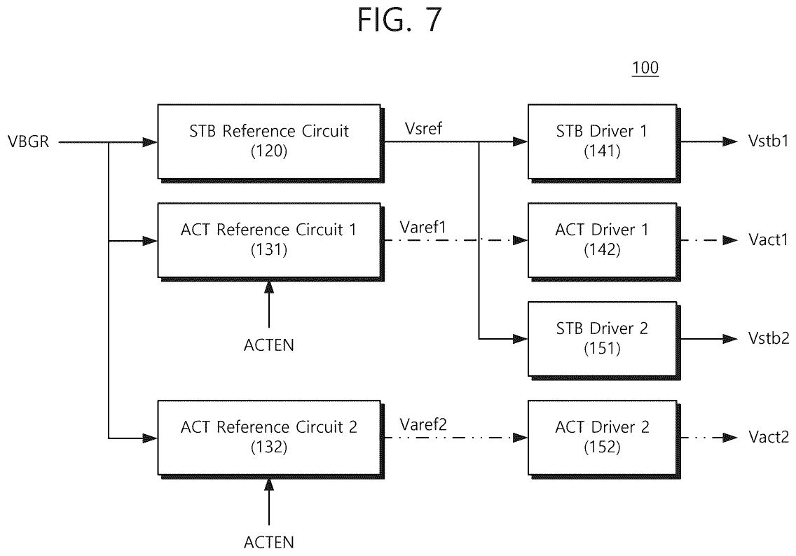

FIG. 7 is a diagram illustrating another example of an operation of the internal power generating circuit of FIG. 3 during an active mode. Referring to FIGS. 3 and 7, in the active mode, an active enable signal ACTEN output from the control logic 1160 of FIG. 2 may be input to the first active reference circuit 131 and the second active reference circuit 132. The bandgap reference voltage VBGR output from the bandgap voltage reference circuit 110 of FIG. 3 may be commonly supplied to the standby reference circuit 120, the first active reference circuit 131 and the second active reference circuit 132.

The first active reference circuit 131 and the second active reference circuit 132 may be activated or deactivated based on an input control signal (for example, a standby enable signal STBEN or an active enable signal ACTEN). In the active mode, when the active enable signal ACTEN is received, the first active reference circuit 131 and the second active reference circuit 132 may be activated and output active reference voltages. In the active mode, the first active reference circuit 131 may output the first active reference voltage Varef1 based on the bandgap reference voltage VBGR. The first active driver 142 may output the first internal active voltage Vact1 based on the first active reference voltage Varef1.

The second active reference circuit 132 may output the second active reference voltage Varef2 based on the bandgap reference voltage VBGR. The second active driver 152 may output the second internal active voltage Vact2 based on the second active reference voltage Varef2. As an example, the first active reference voltage Varef1 may be set differently from the second active reference voltage Varef2. In addition, the first internal active voltage Vact1 may be set differently from the second internal active voltage Vact2. As another example, the first active reference voltage Varef1 may be set identically to the second active reference voltage Varef2. In addition, the first internal active voltage Vact1 may be set identically to the second internal active voltage Vact2.

Even in the active mode, the standby reference circuit 120 may output the standby reference voltage Vsref based on the bandgap reference voltage VBGR. The first standby driver 141 and the second standby driver 151 may commonly receive the standby reference voltage Vsref. The first standby driver 141 may output the first internal standby voltage Vstb1 based on the standby reference voltage Vsref. The second standby driver 151 may output the second internal standby voltage Vstb2 based on the standby reference voltage Vsref.

The first internal standby voltage Vstb1, the second internal standby voltage Vstb2, the first internal active voltage Vact1 or the second internal active voltage Vact2 may be set to be equal to or different from each other. As an example, the first internal standby voltage Vstb1 and the second internal standby voltage Vstb2 may be set identically to the standby reference voltage Vsref. As another example, the first internal standby voltage Vstb1 may be set to be different from the second internal standby voltage Vstb2.

As another example, one of the first internal active voltage Vact1 or the second internal active voltage Vact2 may be set to be equal to one of the first internal standby voltage Vstb1 or the second internal standby voltage Vstb2. As another example, the first internal standby voltage Vstb1, the second internal standby voltage Vstb2, the first internal active voltage Vact1 and the second internal active voltage Vact2 may all be set to be the same.

The first internal standby voltage Vstb1 and the first internal active voltage Vact1 may be integrated and provided to the first internal circuit 1001 as the first internal power signal Pout1. The second internal standby voltage Vstb2 and the second internal active voltage Vact2 may be integrated and provided to the second internal circuit 1002 as the second internal power signal Pout2. As described above, the internal power generating circuit 100 may generate internal power signals to be provided to internal circuits in the active mode through a plurality of active reference circuits.

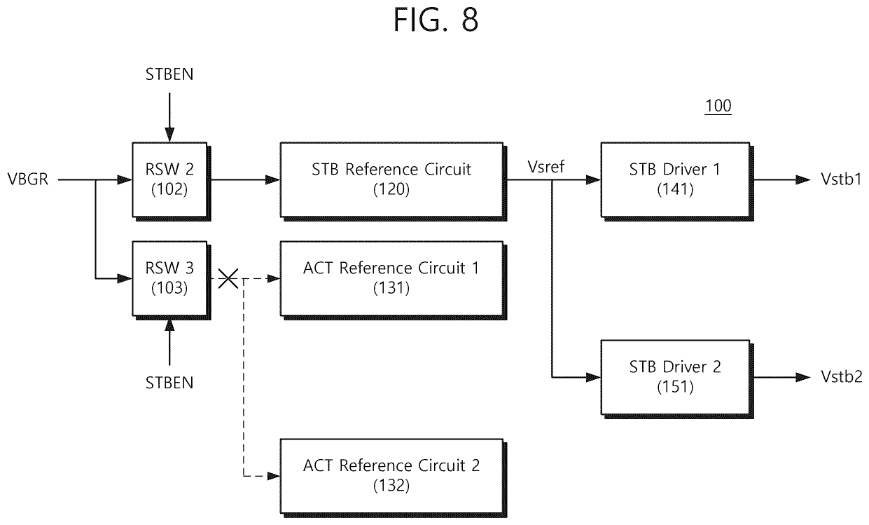

FIG. 8 is a diagram illustrating another example of an operation of the internal power generating circuit of FIG. 3 during a standby mode. Referring to FIGS. 3 and 8, the internal power generating circuit 100 may further include a second reference switch 102 and a third reference switch 103 which control a flow of the bandgap reference voltage VBGR according to operation modes. The bandgap reference voltage VBGR output from the bandgap voltage reference circuit 110 of FIG. 3 may be commonly transmitted to the second reference switch 102 and the third reference switch 103.

The bandgap reference voltage VBGR may be transmitted to the standby reference circuit 120 through the second reference switch 102. The second reference switch 102 may transmit or block the bandgap reference voltage VBGR based on a control signal (for example, a standby enable signal STBEN or an active enable signal ACTEN). In the standby mode, the second reference switch 102 may transmit the bandgap reference voltage VBGR to the standby reference circuit 120 based on the standby enable signal STBEN.

The bandgap reference voltage VBGR may be commonly transmitted to the first active reference circuit 131 and the second active reference circuit 132 through the third reference switch 103. The third reference switch 103 may transmit or block the bandgap reference voltage VBGR based on a control signal (for example, a standby enable signal STBEN or an active enable signal ACTEN).

In the standby mode, based on the standby enable signal STBEN, the third reference switch 103 may block the bandgap reference voltage VBGR transmitted to the first active reference circuit 131 and the second active reference circuit 132. In the standby mode, the standby reference circuit 120 may output the standby reference voltage Vsref based on the bandgap reference voltage VBGR. The first standby driver 141 and the second standby driver 151 may commonly receive the standby reference voltage Vsref.

The first standby driver 141 may output the first internal standby voltage Vstb1 based on the standby reference voltage Vsref. The second standby driver 151 may output the second internal standby voltage Vstb2 based on the standby reference voltage Vsref. As an example, the first internal standby voltage Vstb1 and the second internal standby voltage Vstb2 may be set identically to the standby reference voltage Vsref. As another example, the first internal standby voltage Vstb1 and the second internal standby voltage Vstb2 may be set to be different from each other.

The first internal power signal Pout1 having the first internal standby voltage Vstb1 may be provided to the first internal circuit 1001. The second internal power signal Pout2 having the second internal standby voltage Vstb2 may be provided to the second internal circuit 1002. As described above, the internal power generating circuit 100 may generate internal power signals to be provided to internal circuits in the standby mode through one standby reference circuit 120.

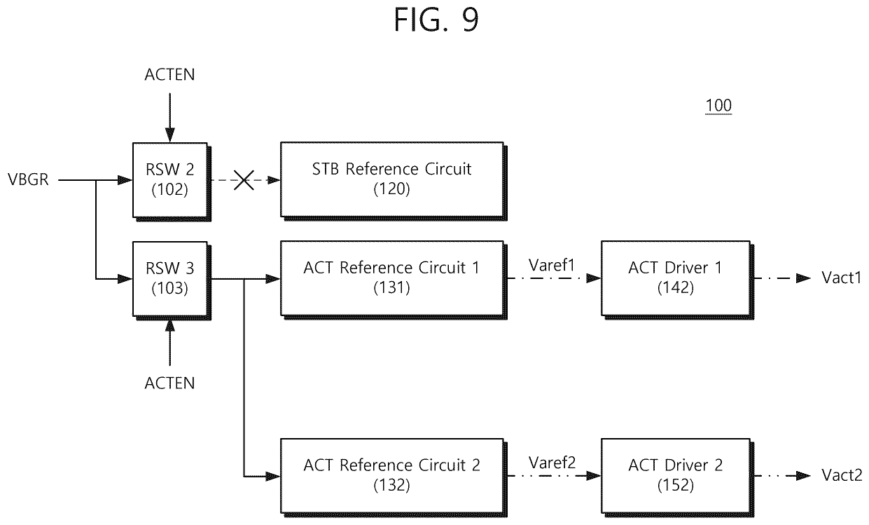

FIG. 9 is a diagram illustrating another example of an operation of the internal power generating circuit of FIG. 3 during an active mode. Referring to FIGS. 3 and 9, the internal power generating circuit 100 may further include a second reference switch 102 and a third reference switch 103 which control a flow of the bandgap reference voltage VBGR according to operation modes. The bandgap reference voltage VBGR output from the bandgap voltage reference circuit 110 of FIG. 3 may be commonly transmitted to the second reference switch 102 and the third reference switch 103.

The bandgap reference voltage VBGR may be transmitted to the standby reference circuit 120 through the second reference switch 102. The second reference switch 102 may transmit or block the bandgap reference voltage VBGR based on a control signal (for example, a standby enable signal STBEN or an active enable signal ACTEN). In the active mode, the second reference switch 102 may block the bandgap reference voltage VBGR transmitted to the standby reference circuit 120 based on the active enable signal ACTEN.

The bandgap reference voltage VBGR may be commonly transmitted to the first active reference circuit 131 and the second active reference circuit 132 through the third reference switch 103. The third reference switch 103 may transmit or block the bandgap reference voltage VBGR based on a control signal (for example, a standby enable signal STBEN or an active enable signal ACTEN). In the active mode, based on the active enable signal ACTEN, the third reference switch 103 may transmit the bandgap reference voltage VBGR to the first active reference circuit 131 and the second active reference circuit 132.

In the active mode, the first active reference circuit 131 may output the first active reference voltage Varef1 based on the bandgap reference voltage VBGR. The first active driver 142 may output the first internal active voltage Vact1 based on the first active reference voltage Varef1.

The second active reference circuit 132 may output the second active reference voltage Varef2 based on the bandgap reference voltage VBGR. The second active driver 152 may output the second internal active voltage Vact2 based on the second active reference voltage Varef2.

As an example, the first active reference voltage Varef1 may be set differently from the second active reference voltage Varef2. In addition, the first internal active voltage Vact1 may be set differently from the second internal active voltage Vact2. As another example, the first active reference voltage Varef1 may be set identically to the second active reference voltage Varef2. In addition, the first internal active voltage Vact1 may be set identically to the second internal active voltage Vact2.

The first internal power signal Pout1 having the first internal active voltage Vact1 may be provided to the first internal circuit 1001. The second internal power signal Pout2 having the second internal active voltage Vact2 may be provided to the second internal circuit 1002. As described above, the internal power generating circuit 100 may generate internal power signals to be provided to internal circuits in the active mode through a plurality of active reference circuits.

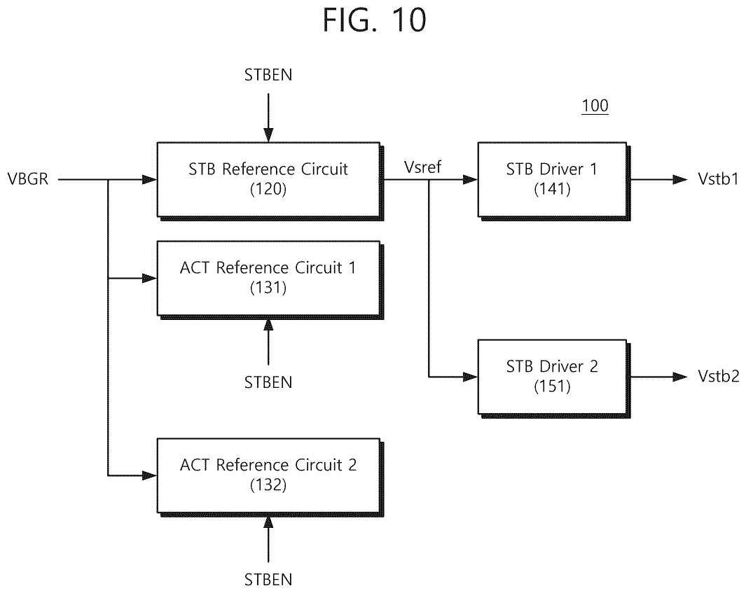

FIG. 10 is a diagram illustrating another example of an operation of the internal power generating circuit of FIG. 3 during a standby mode. Referring to FIGS. 3 and 10, in the standby mode, the standby enable signal STBEN output from the control logic 1160 of FIG. 2 may be input to the standby reference circuit 120, the first active reference circuit 131 and the second active reference circuit 132. The bandgap reference voltage VBGR output from the bandgap voltage reference circuit 110 of FIG. 3 may be commonly supplied to the standby reference circuit 120, the first active reference circuit 131 and the second active reference circuit 132.

The standby reference circuit 120 may be activated or deactivated based on a control signal (for example, a standby enable signal STBEN or an active enable signal ACTEN). In the standby mode, when the standby enable signal STBEN is received, the standby reference circuit 120 may be activated and output a standby reference voltage Vsref. The first active reference circuit 131 and the second active reference circuit 132 may be activated or deactivated based on a control signal (for example, a standby enable signal STBEN or an active enable signal ACTEN). In the standby mode, when the standby enable signal STBEN is received, the first active reference circuit 131 and the second active reference circuit 132 may be deactivated and not output active reference voltages.

In the standby mode, the standby reference circuit 120 may output the standby reference voltage Vsref based on the bandgap reference voltage VBGR. The first standby driver 141 and the second standby driver 151 may commonly receive the standby reference voltage Vsref. The first standby driver 141 may output the first internal standby voltage Vstb1 based on the standby reference voltage Vsref. The second standby driver 151 may output the second internal standby voltage Vstb2 based on the standby reference voltage Vsref.

As an example, the first internal standby voltage Vstb1 and the second internal standby voltage Vstb2 may be set identically to the standby reference voltage Vsref. As another example, the first internal standby voltage Vstb1 and the second internal standby voltage Vstb2 may be set differently from each other.

The first internal power signal Pout1 having the first internal standby voltage Vstb1 may be provided to the first internal circuit 1001. The second internal power signal Pout2 having the second internal standby voltage Vstb2 may be provided to the second internal circuit 1002. As described above, the internal power generating circuit 100 may generate internal power signals to be provided to internal circuits in the standby mode through one standby reference circuit 120.

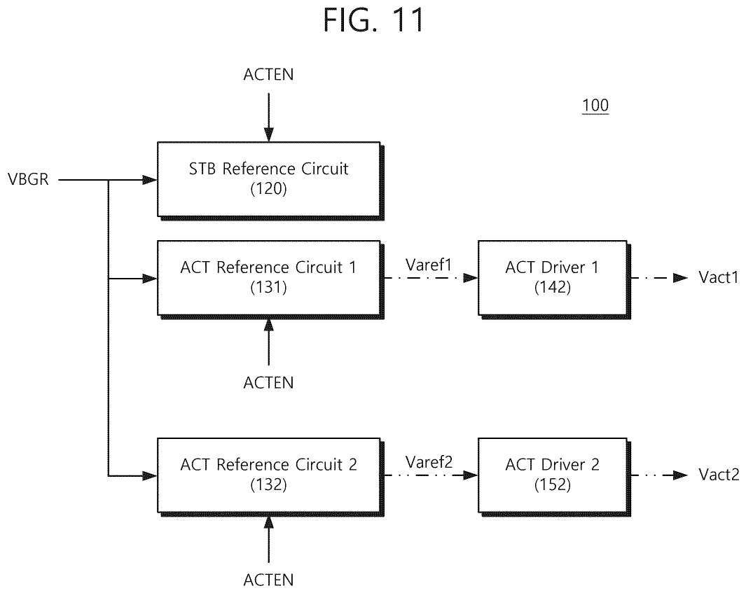

FIG. 11 is a diagram illustrating another example of an operation of the internal power generating circuit of FIG. 3 during an active mode. Referring to FIGS. 3 and 11, in the active mode, an active enable signal ACTEN output from the control logic 1160 of FIG. 2 may be input to the standby reference circuit 120, the first active reference circuit 131 and the second active reference circuit 132. The bandgap reference voltage VBGR output from the bandgap voltage reference circuit 110 of FIG. 3 may be commonly provided to the standby reference circuit 120, the first active reference circuit 131 and the second active reference circuit 132.

The standby reference circuit 120 may be activated or deactivated based on a control signal (for example, a standby enable signal STBEN or an active enable signal ACTEN). In the active mode, when the active enable signal ACTEN is received, the standby reference circuit 120 may be deactivated and not output the standby reference voltage.

The first active reference circuit 131 and the second active reference circuit 132 may be activated or deactivated based on a control signal (for example, the standby enable signal STBEN or the active enable signal ACTEN). In the active mode, when the active enable signal ACTEN is received, the first active reference circuit 131 and the second active reference circuit 132 may be activated and output active reference voltages.

In the active mode, the first active reference circuit 131 may output the first active reference voltage Varef1 based on the bandgap reference voltage VBGR. The first active driver 142 may output the first internal active voltage Vact1 based on the first active reference voltage Varef1. The second active reference circuit 132 may output the second active reference voltage Varef2 based on the bandgap reference voltage VBGR. The second active driver 152 may output the second internal active voltage Vact2 based on the second active reference voltage Varef2.

As an example, the first active reference voltage Varef1 may be set differently from the second active reference voltage Varef2. In addition, the first internal active voltage Vact1 may be set differently from the second internal active voltage Vact2.

As another example, the first active reference voltage Varef1 may be set identically to the second active reference voltage Varef2. In addition, the first internal active voltage Vact1 may be set identically to the second internal active voltage Vact2.

The first internal power signal Pout1 having the first internal active voltage Vact1 may be provided to the first internal circuit 1001. The second internal power signal Pout2 having the second internal active voltage Vact2 may be provided to the second internal circuit 1002. As described above, the internal power generating circuit 100 may generate internal power signals to be provided to internal circuits in the active mode through a plurality of active reference circuits.

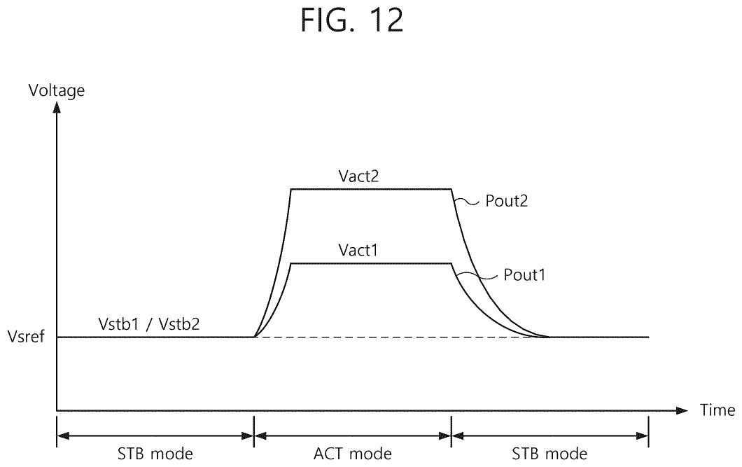

FIG. 12 is a graph illustrating voltage levels of internal power signals output from the internal power generating circuit of FIG. 3 according to operation modes of the memory device of FIG. 2. Referring to FIGS. 3 and 12, the internal power generating circuit 100 may output a first internal power signal Pout1 and a second internal power signal Pout2 according to a standby mode STB mode or an active mode ACT mode.

In the standby mode, both the first internal power signal Pout1 and the second internal power signal Pout2 may be set to internal standby voltages (for example, the first internal standby voltage Vstb1 and the second internal standby voltage Vstb2) based on the standby reference voltage Vsref output by the standby reference circuit 120.

In the active mode, the first internal power signal Pout1 and the second internal power signal Pout2 may be set their internal active voltages by their respective active reference circuits. For example, the first internal power signal Pout1 may be set to the first internal active voltage Vact1 based on the first active reference voltage Varef1 output by the first active reference circuit 131. The second internal power signal Pout2 may be set to the second internal active voltage Vact2 based on the second active reference voltage Varef2 output by the second active reference circuit 132.

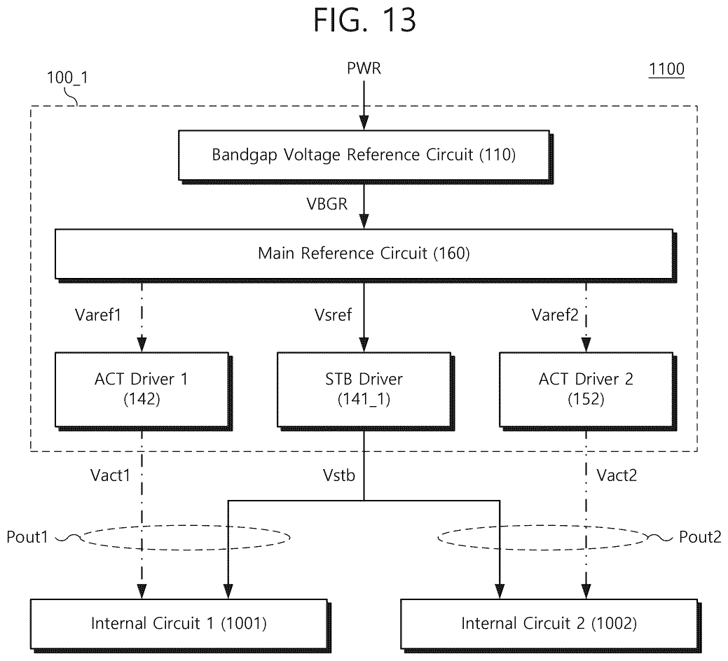

FIG. 13 is a block diagram illustrating another example of components included in the internal power generating circuit of FIG. 2. Referring to FIGS. 2 and 13, the internal power generating circuit 100_1 may generate a first internal power signal Pout1 and a second internal power signal Pout2 supplied to a first internal circuit 1001 and a second internal circuit 1002 based on the external supply power PWR.

The internal power generating circuit 100_1 may include a bandgap voltage reference circuit 110, a main reference circuit 160, a standby driver 141_1, a first active driver 142 and/or a second active driver 152. The bandgap voltage reference circuit 110 may generate the bandgap reference voltage VBGR based on the external supply power PWR. For example, the bandgap voltage reference circuit 110 may output the constant bandgap reference voltage VBGR regardless of changes in PVT (Process, Voltage and/or Temperature). The bandgap reference voltage VBGR may be supplied to the main reference circuit 160.

The main reference circuit 160 may generate a plurality of reference voltages based on the bandgap reference voltage VBGR. For example, the main reference circuit 160 may generate a standby reference voltage Vsref based on the bandgap reference voltage VBGR. The main reference circuit 160 may generate a first active reference voltage Varef1 based on the bandgap reference voltage VBGR. The main reference circuit 160 may generate a second active reference voltage Varef2 based on the bandgap reference voltage VBGR.

The internal power generating circuit 100_1 may generate the standby reference voltage Vsref, the first active reference voltage Varef1 and/or the second active reference voltage Varef2 having different voltage levels through one main reference circuit 160. Accordingly, compared to the internal power generating circuit 100 of FIG. 3 which uses multiple reference circuits for each of reference voltages, the internal power generating circuit 100_1 may reduce a current used by one main reference circuit 160.

In the standby mode and/or the active mode, the main reference circuit 160 may output the standby reference voltage Vsref. The standby driver 141_1 may generate an internal standby voltage Vstb based on the standby reference voltage Vsref. The internal standby voltage Vstb may be provided in common to the first internal circuit 1001 and the second internal circuit 1002. As an example, the internal standby voltage Vstb may be the same as the standby reference voltage Vsref.

For example, the standby driver 141_1 may be a small driver having a relatively smaller operating current compared to the first active driver 142 and the second active driver 152. The standby driver 141_1 may be a small driver which provides only the minimum voltage necessary to maintain a standby state of the first internal circuit 1001 and the second internal circuit 1002 in the standby mode.

As an example, the standby reference voltage Vsref may be provided to the standby driver 141_1 both in the standby mode and in the active mode. As another example, the standby reference voltage Vsref may be provided to the standby driver 141_1 in the standby mode and may be blocked in the active mode.

In the active mode, the main reference circuit 160 may output the first active reference voltage Varef1. The first active driver 142 may generate the first internal active voltage Vact1 based on the first active reference voltage Varef1. As an example, in the active mode, the first internal active voltage Vact1 may be combined with the internal standby voltage Vstb and supplied to the first internal circuit 1001 as the first internal power signal Pout1. As another example, in the active mode, only the first internal active voltage Vact1 may be supplied to the first internal circuit 1001 as the first internal power signal Pout1.

In the active mode, the main reference circuit 160 may output the second active reference voltage Varef2. The second active driver 152 may generate the second internal active voltage Vact2 based on the second active reference voltage Varef2. As an example, in the active mode, the second internal active voltage Vact2 may be combined with the internal standby voltage Vstb to be supplied to the second internal circuit 1002 as the second internal power signal Pout2. As another example, in the active mode, only the second internal active voltage Vact2 may be supplied to the second internal circuit 1002 as the second internal power signal Pout2.

As an example, the first active reference voltage Varef1 may be generated differently from the second active reference voltage Varef2. Similarly, the first internal active voltage Vact1 may be generated differently from the second internal active voltage Vact2. As another example, the first active reference voltage Varef1 may be generated identically to the second active reference voltage Varef2. Similarly, the first internal active voltage Vact1 may be generated identically to the second internal active voltage Vact2.

The first active driver 142 and the second active driver 152 may be large drivers having relatively greater operating currents compared to the standby driver 141_1. Accordingly, in the active mode, the first internal power signal Pout1 may have the first internal active voltage Vact1 regardless of a combination with the internal standby voltage Vstb. Similarly, in the active mode, the second internal power signal Pout2 may have the second internal active voltage Vact2 regardless of a combination with the internal standby voltage Vstb.

As described above, the internal power generating circuit 1001 may generate one standby reference voltage Vsref for the plurality of standby power signals supplied to the plurality of internal circuits (for example, the first internal circuit 1001 and the second internal circuit 1002) through one main reference circuit 160 in the standby mode. Accordingly, compared to a method of using multiple standby reference circuits corresponding to multiple internal circuits, the internal power generating circuit 100_1 may have a reduced area, and a current consumed for generating the standby reference voltage Vsref in the standby mode may be reduced.

In addition, the internal power generating circuit 1001 may generate multiple active reference voltages (for example, the first active reference voltage Varef1 and the second active reference voltage Varef2) corresponding to multiple internal circuits (for example, the first internal circuit 1001 and the second internal circuit 1002) in the active mode. Accordingly, the internal power generating circuit 1001 may individually or independently control multiple active power signals supplied to multiple internal circuits in the active mode.

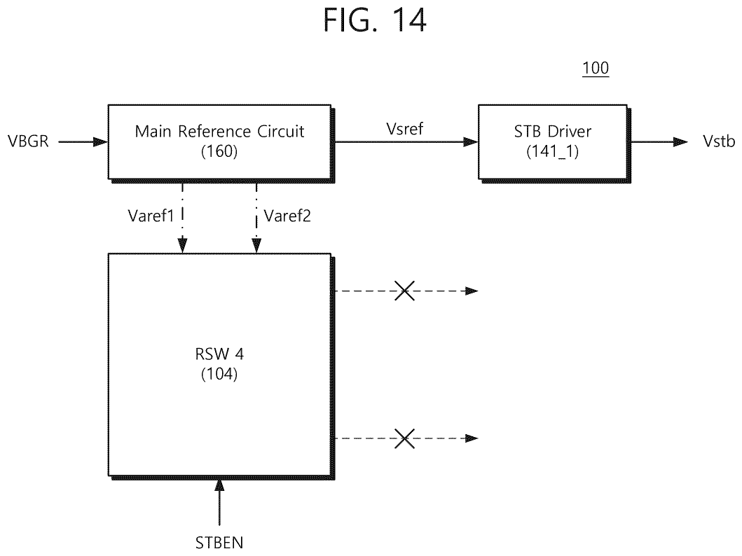

FIG. 14 is a diagram illustrating an example embodiment of an operation of the internal power generating circuit of FIG. 13 during a standby mode. Referring to FIGS. 13 and 14, the internal power generating circuit 1001 may further include a fourth reference switch 104 which controls a flow of the first active reference voltage Varef1 and the second active reference voltage Varef2 depending on operation modes. The first active reference voltage Varef1 and the second active reference voltage Varef2 may be transmitted or blocked to the first active driver 142 and the second active driver 152 through the fourth reference switch 104.

In the standby mode, based on the standby enable signal STBEN, the fourth reference switch 104 may block the first active reference voltage Varef1 and the second active reference voltage Varef2 transmitted to the first active driver 142 and the second active driver 152. As an example, the fourth reference switch 104 may be configured with two switches corresponding to the first active reference voltage Varef1 and the second active reference voltage Varef2, respectively.

In the standby mode, the main reference circuit 160 may output the standby reference voltage Vsref based on the bandgap reference voltage VBGR. The standby driver 141_1 may output the internal standby voltage Vstb based on the standby reference voltage Vsref. The internal standby voltage Vstb may be commonly provided to the first internal circuit 1001 and the second internal circuit 1002.

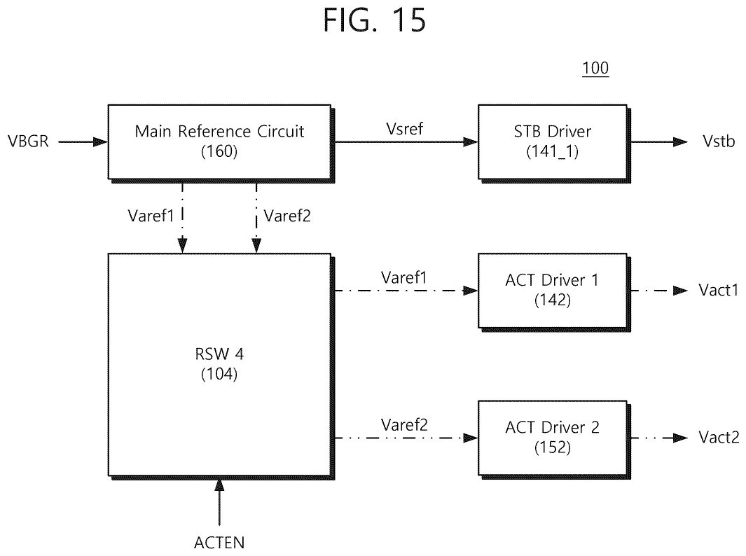

FIG. 15 is a diagram illustrating an example embodiment of an operation of the internal power generating circuit of FIG. 13 during an active mode. Referring to FIGS. 13 and 15, the internal power generating circuit 1001 may further include a fourth reference switch 104 which controls a flow of the first active reference voltage Varef1 and the second active reference voltage Varef2 according to operation modes.

The first active reference voltage Varef1 and the second active reference voltage Varef2 may be transmitted or blocked to the first active driver 142 and the second active driver 152 through the fourth reference switch 104.

In the active mode, based on the active enable signal ACTEN, the fourth reference switch 104 may transmit the first active reference voltage Varef1. In addition, the fourth reference switch 104 may transmit the second active reference voltage Varef2 to the second active driver 152.

As an example, the fourth reference switch 104 may be configured with two switches corresponding to the first active reference voltage Varef1 and the second active reference voltage Varef2, respectively.

Even in the active mode, the main reference circuit 160 may output the standby reference voltage Vsref based on the bandgap reference voltage VBGR. The standby driver 141_1 may output the internal standby voltage Vstb based on the standby reference voltage Vsref.

The first internal active voltage Vact1 may be combined with the internal standby voltage Vstb and provided to the first internal circuit 1001 as the first internal power signal Pout1. The second internal active voltage Vact2 may be combined with the internal standby voltage Vstb and provided to the second internal circuit 1002 as the second internal power signal Pout2.

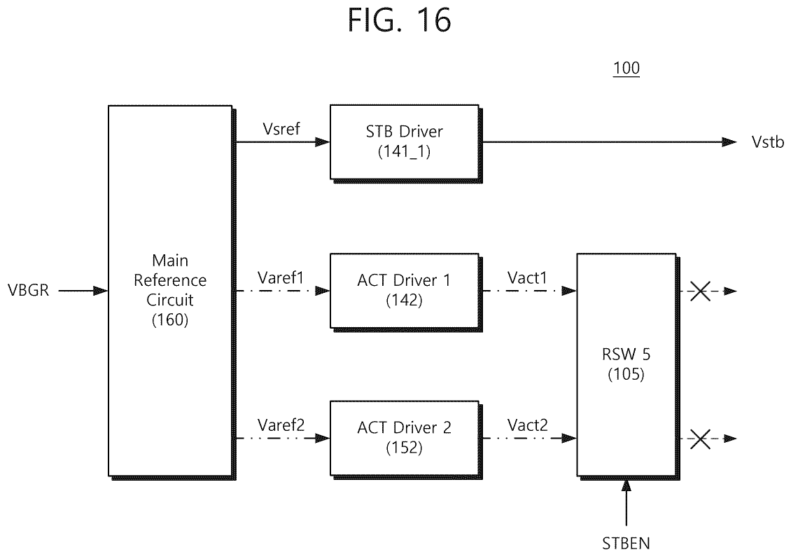

FIG. 16 is a diagram illustrating another example of an operation of the internal power generating circuit of FIG. 13 during a standby mode. Referring to FIGS. 13 and 16, the internal power generating circuit 100_1 may further include a fifth reference switch 105 which controls a flow of the first internal active voltage Vact1 and the second internal active voltage Vact2 according to operation modes.

The first internal active voltage Vact1 and the second internal active voltage Vact2 may be transmitted or blocked to the first internal circuit 1001 and the second internal circuit 1002 through the fifth reference switch 105.

In the standby mode, based on the standby enable signal STBEN, the fifth reference switch 105 may block the first internal active voltage Vact1 transmitted to the first internal circuit 1001. In addition, the fifth reference switch 105 may block the second internal active voltage Vact2 transmitted to the second internal circuit 1002.

As an example, the fifth reference switch 105 may be combined with two switches corresponding to the first internal active voltage Vact1 and the second internal active voltage Vact2, respectively.

In the standby mode, the main reference circuit 160 may output the standby reference voltage Vsref based on the bandgap reference voltage VBGR. The standby driver 141_1 may output the internal standby voltage Vstb based on the standby reference voltage Vsref. The internal standby voltage Vstb may be commonly provided to the first internal circuit 1001 and the second internal circuit 1002.

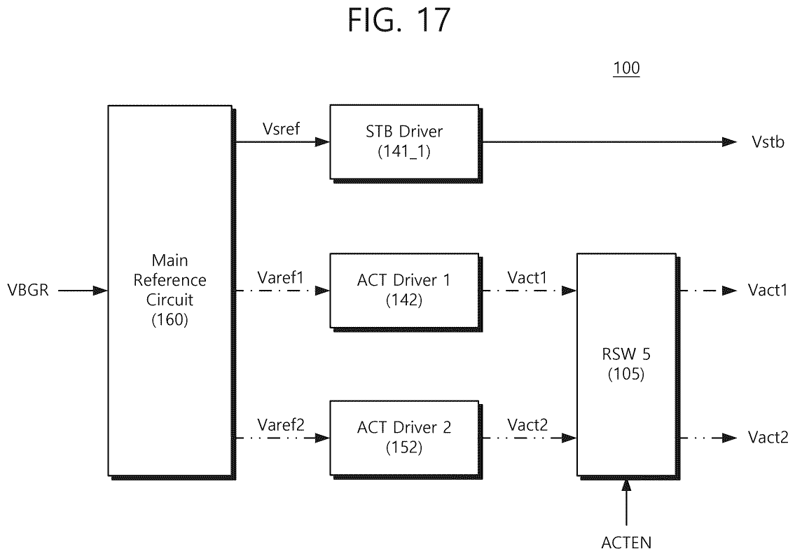

FIG. 17 is a diagram illustrating another example of an operation of the internal power generating circuit of FIG. 13 during an active mode. Referring to FIGS. 13 and 17, the internal power generating circuit 100_1 may further include a fifth reference switch 105 which controls a flow of the first internal active voltage Vact1 and the second internal active voltage Vact2 according to operation modes.

The first internal active voltage Vact1 and the second internal active voltage Vact2 may be transmitted or blocked to the first internal circuit 1001 and the second internal circuit 1002 through the fourth reference switch 104.

In the active mode, based on the active enable signal ACTEN, the fifth reference switch 105 may transmit the first internal active voltage Vact1 to the first internal circuit 1001. In addition, the fifth reference switch 105 may transmit the second internal active voltage Vact2 to the second internal circuit 1002.

As an example, the fifth reference switch 105 may be configured with two switches corresponding to the first internal active voltage Vact1 and the second internal active voltage Vact2, respectively.

Even in the active mode, the main reference circuit 160 may output the standby reference voltage Vsref based on the bandgap reference voltage VBGR. The standby driver 141_1 may output the internal standby voltage Vstb based on the standby reference voltage Vsref. The first internal active voltage Vact1 may be combined with the internal standby voltage Vstb and provided to the first internal circuit 1001 as the first internal power signal Pout1. The second internal active voltage Vact2 may be combined with the internal standby voltage Vstb and provided to the second internal circuit 1002 as the second internal power signal Pout2.

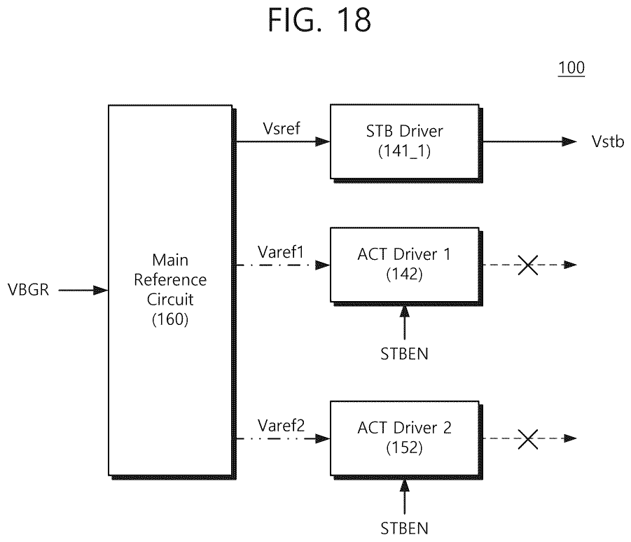

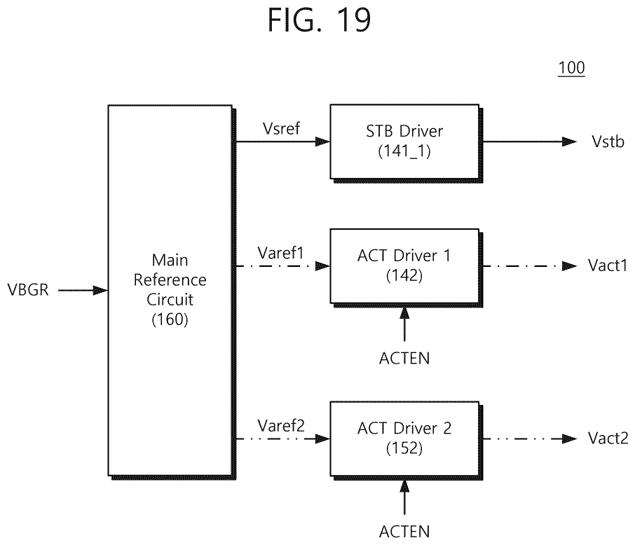

FIG. 18 is a diagram illustrating another example of an operation of the internal power generating circuit of FIG. 13 during a standby mode. FIG. 19 is a diagram illustrating another example of an operation of the internal power generating circuit of FIG. 13 during an active mode. Referring to FIGS. 13, 18 and 19, the first active driver 142 and the second active driver 152 may output or block the first internal active voltage Vact1 and the second internal active voltage Vact2 based on a control signal (for example, a standby enable signal STBEN or an active enable signal ACTEN).

Referring to FIG. 18, in the standby mode, the main reference circuit 160 may output the standby reference voltage Vsref, the first active reference voltage Varef1 and/or the second active reference voltage Varef2 based on the bandgap reference voltage VBGR. The standby driver 141_1 may output the internal standby voltage Vstb based on the standby reference voltage Vsref.

However, when the standby enable signal STBEN is received, the first active driver 142 and the second active driver 152 may be deactivated. For example, the first active driver 142 may receive the first active reference voltage Varef1, but may not output the first internal active voltage Vact1 based on the standby enable signal STBEN. The second active driver 152 may receive the second active reference voltage Varef2, but may not output the second internal active voltage Vact2 based on the standby enable signal STBEN.

Referring to FIG. 19, in the active mode, the main reference circuit 160 may output the standby reference voltage Vsref, the first active reference voltage Varef1 and/or the second active reference voltage Varef2 based on the bandgap reference voltage VBGR. The standby driver 141_1 may output the internal standby voltage Vstb based on the standby reference voltage Vsref.

When the active enable signal ACTEN is received, the first active driver 142 and the second active driver 152 may be activated. For example, the first active driver 142 may receive the first active reference voltage Varef1 and output the first internal active voltage Vact1 based on the active enable signal ACTEN. The second active driver 152 may receive the second active reference voltage Varef2 and output the second internal active voltage Vact2 based on the active enable signal ACTEN.

According to another embodiment, although not illustrated, the standby driver 141_1 may be activated or deactivated based on a control signal (for example, the standby enable signal STBEN or the active enable signal ACTEN). For example, when the standby enable signal STBEN is received, the standby driver 141_1 may be activated and output the internal standby voltage Vstb based on the standby reference voltage Vsref. When an active enable signal ACTEN is received, the standby driver 141_1 may be deactivated and not output the internal standby voltage Vstb.

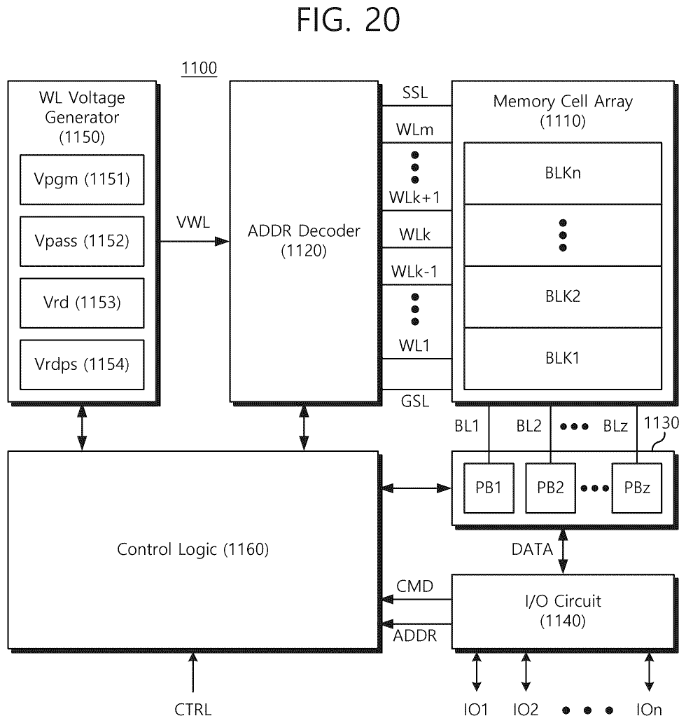

FIG. 20 is a block diagram illustrating an example embodiment of the memory device illustrated in FIG. 1. The storage device 1000 of FIG. 1 may be a flash storage device based on a flash memory. For example, the storage device 1000 may be implemented as a solid state drive (SSD), a universal flash storage (UFS), a memory card, or the like.

Referring to FIGS. 1 and 20, The memory device 1100 may include the memory cell array 1110 and the peripheral circuit. The peripheral circuit may include an address decoder 1120, a page buffer circuit 1130, an input/output circuit 1140, a wordline voltage generator 1150, and a control block 1160.

The memory cell array 1110 may include a plurality of memory blocks BLK1 to BLKn. Each memory block may be composed of a plurality of pages. Each page may include a plurality of memory cells. Each memory cell may store multi-bit data (for example, two or more bits). Each memory block may correspond to an erase unit, and each page may correspond to a read and/or write unit.

For example, each of memory blocks may have a planar 2D structure or a vertical 3D structure. In a memory block having a 2D structure (or planar structure), memory cells may be formed in a horizontal direction with respect to a substrate. In a memory block having a 3D structure (or vertical structure), memory cells may be formed in a vertical direction with respect to a substrate.

As an example, in the memory block having the 3D structure (or vertical structure), a gate electrode layer and an insulation layer may be alternately deposited on the substrate. Each memory block (for example, BLK1) may be connected to one or more string selection lines SSL, a plurality of wordlines WL1 to WLm, and one or more ground selection lines GSL. WLk is a selected wordline sWL and the remaining wordlines (WL1 to WLk−1, WLk+1 to WLm) are unselected wordlines uWL.

The address decoder 1120 may be connected to the memory cell array 1110 through selection lines SSL and GSL and wordlines WL1 to WLm. The address decoder 1120 may select a wordline during a program or read operation. The address decoder 1120 may receive the wordline voltage VWL from the wordline voltage generator 1150 and provide a program voltage or read voltage to the selected wordline.

The page buffer circuit 1130 may be connected to the memory cell array 1110 through bitlines BL1 to BLz. The page buffer circuit 1130 may temporarily store data to be stored in the memory cell array 1110 or data read from the memory cell array 1110. The page buffer circuit 1130 may include page buffers PB1 to PBz connected to respective bitlines. Each page buffer may include a plurality of latches to store or read multi-bit data.

The input/output circuit 1140 may be internally connected to the page buffer circuit 1130 through data lines and externally connected to the memory controller (referring to FIG. 1, 1200) through the input/output lines IO1 to IOn. The input/output circuit 1140 may receive program data from the memory controller 1200 during a program operation. In addition, the input/output circuit 1140 may provide data read from the memory cell array 1110 to the memory controller 1200 during a read operation.

The wordline voltage generator 1150 may receive internal power from the control block 1160 and generate a wordline voltage VWL required to read or write data. The wordline voltage VWL may be provided to a selected wordline or unselected wordlines through the address decoder 1120.

The wordline voltage generator 1150 may include a program voltage generator 1151 and a pass voltage generator 1152. The program voltage generator 1151 may generate a program voltage provided to the selected wordline during a program operation. The pass voltage generator 1152 may generate a pass voltage provided to the selected wordline and the unselected wordlines.

The wordline voltage generator 1150 may include a read voltage generator 1153 and a read pass voltage generator 1154. The read voltage generator 1153 may generate a select read voltage provided to the select wordline during a read operation. The read pass voltage generator 1154 may generate a read pass voltage provided to unselected wordlines. The read pass voltage may be a voltage sufficient to turn on memory cells connected to the unselected wordlines during a read operation.

The control logic 1160 may control operations such as read, write, and erase of the memory device 1100 using commands CMD, addresses ADDR and/or control signals CTRL provided from the memory controller 1200. The addresses ADDR may include a block selection address for selecting one memory block, a row address for selecting one page and/or a column address for selecting one memory cell.

The configurations of the memory device 1100 illustrated in FIG. 20 may be supplied with internal power (for example, Pout1 to Poutn) from the internal power generation circuit 100 of FIG. 1 and FIG. 2. The internal power (for example, Pout1 to Poutn) may be changed depending on the standby mode or the active mode.

In the active mode, the internal power generation circuit 100 may individually supply active internal power at a voltage level required by each of the configurations of the memory device 1100 illustrated in FIG. 20 through a plurality of active reference circuits (for example, the first active reference circuit 131 and/or the second active reference circuit 132).

In the standby mode, the internal power generation circuit 100 may supply a standby internal power having a common voltage level to the configurations of the memory device 1100 illustrated in FIG. 20 through one standby reference circuit (for example, the standby reference circuit 120).

Accordingly, the memory device 1100 may reduce standby power in the standby mode, while supplying individual or independent internal power to the configurations of the memory device 1100 illustrated in FIG. 20 in the active mode.

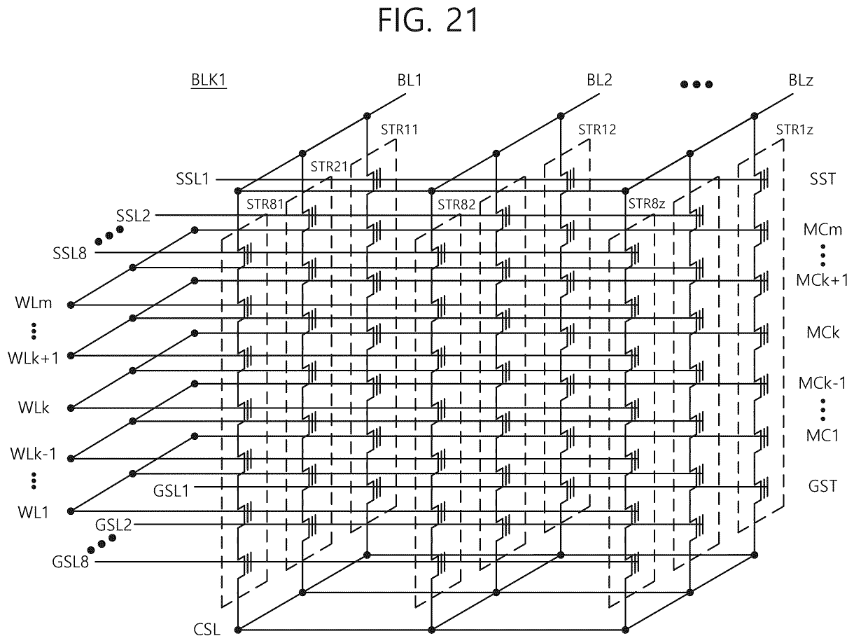

FIG. 21 is a circuit diagram illustrating an example embodiment of a memory block BLK1 of a memory cell array illustrated in FIG. 20. Referring to FIG. 21, in the memory block BLK1, a plurality of cell strings STR11 to STR8z may be formed between the bit lines BL1 to BLz and a common source line CSL. Each cell string may include a string selection transistor SST, a plurality of memory cells MC1 to MCm and/or a ground selection transistor GST.

The string selection transistors SST may be connected with string selection lines SSL1 to SSL8. The ground selection transistors GST may be connected with ground selection lines GSL1 to GSL8. The string selection transistors SST may be connected with the bit lines BL1 to BLz, and the ground selection transistors GST may be connected with the common source line CSL.

The first to m-th wordlines WL1 to WLm may be connected with the plurality of memory cells MC1 to MCm in a row direction. The first to z-th bit lines BL1 to BLz may be connected with the plurality of memory cells MC1 to MCm in a column direction.

The first wordline WL1 may be placed above the first to eighth ground selection lines GSL1 to GSL8. The first memory cells MC1 that are placed at the same height from the substrate may be connected with the first wordline WL1. The m-th wordline WLm may be placed below the string selection lines SSL1 to SSL8. The m-th memory cells MCm that are placed at the same height from the substrate may be connected with the m-th wordline WLm. In a similar manner, the second to m−1 memory cells MC2 to MCm−1 that are placed at the same heights from the substrate may be respectively connected with the second to m−1 wordlines WL2 to WLm−1.

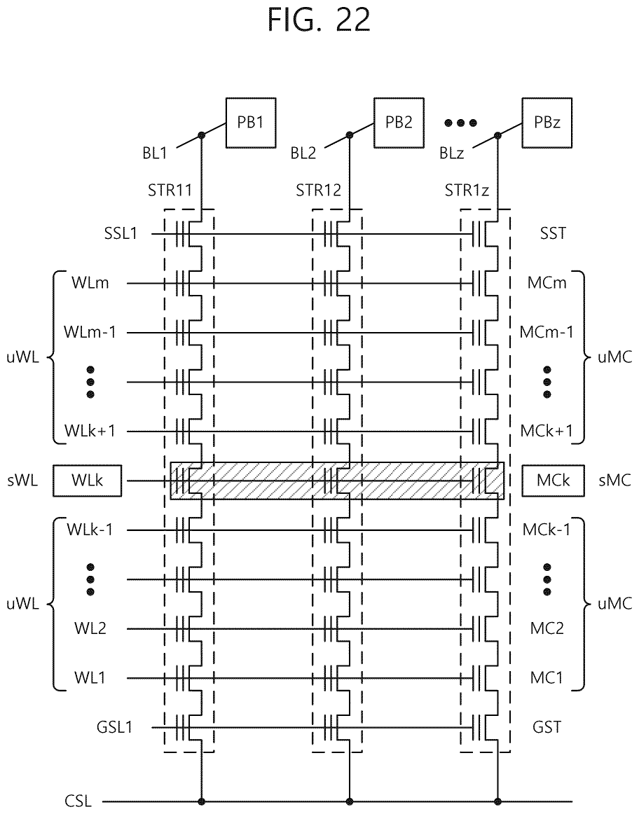

FIG. 22 is a circuit diagram illustrating cell strings selected by a first string selection line SSL1 among cell strings of a memory block BLK1 illustrated in FIG. 21. One-one to one-z cell strings STR11 to STR1z may be selected by the first string selection line SSL1. The one-one to one-z cell strings STR11 to STR1z may be connected to first to z-th bit lines BL1 to BLz, respectively. First to z-th page buffers PB1 to PBz may be connected to the first to z-th bit lines BL1 to BLz, respectively.

The one-one cell string STR11 may be connected to the first bit line BL1 and the common source line CSL. The one-one cell string STR11 may include string selection transistors SST selected by the first string selection line SSL1, first to m-th memory cells MC1 to MCm connected to first to m-th wordlines WL1 to WLm, and ground selection transistors GST selected by first ground selection line GSL1. The one-two cell string STR12 may be connected to the second bit line BL2 and the common source line CSL. The one-z cell string STR1z may be connected to the z-th bit line BLz and the common source line CSL.

The first wordline WL1 and the m-th wordline WLm may be edge wordlines (edge WL). The second wordline WL2 and the m−1 wordline WLm−1 may be edge adjacent wordlines (edge adjacent WL). The k-th wordline WLk may be a selection wordline sWL. The k−1 wordline WLk−1 and the k+1 wordline WLk+1 may be adjacent wordlines located next to the selected wordline. When the k-th wordline WLk is a selected wordline sWL, the remaining wordlines WL1 to WLk−1 and WLk+1 to WLm may be unselected wordlines uWL.

The first memory cells MC1 and the m-th memory cells MCm may be edge memory cells (edge MC). The second memory cells MC2 and the m−1 memory cells MCm−1 may be edge adjacent memory cells (edge adjacent MC). The k-th memory cells MCk may be selection memory cells sMC. The k−1 memory cells MCk−1 and the k+1 memory cells MCk+1 may be memory cells adjacent to the selected memory cells (hereinafter referred to as adjacent memory cells (adjacent MC)). When the k-th memory cells MCk are selected memory cells sMC, the remaining memory cells MC1 to MCk−1 and MCk+1 to MCm may be unselected memory cells uMC.

A set of memory cells selected by one string selection line and connected to one wordline may be one page. For example, memory cells selected by the first string selection line SSL1 and connected to the k-th wordline WLk may constitute one page. For example, eight pages may be configured in the k-th wordline WLk. Among the eight pages, a page connected to the first string selection line SSL1 may be a selected page, and the other pages connected to the second to eighth string selection lines SSL2 to SSL8 may be unselected pages.

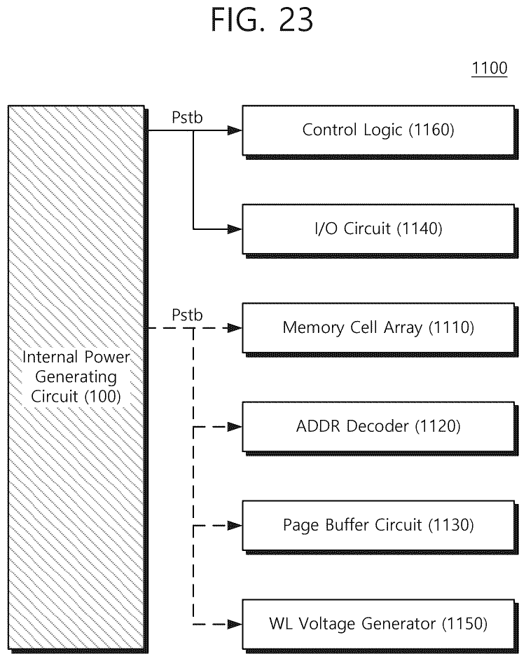

FIG. 23 is a diagram illustrating internal power supplied to the configurations of the memory device of FIG. 20 during a standby mode. Referring to FIG. 23, the internal power generating circuit 100 may generate a common standby reference voltage (for example, the standby reference voltage Vsref) through one standby reference circuit (for example, the standby reference circuit 120 of FIG. 3) in the standby mode. The internal power generating circuit 100 may supply a standby internal power signal Pstb commonly to the configurations of the memory device 1100 of FIG. 20 based on the common standby reference voltage.

According to another embodiment, the internal power generating circuit 100 may supply the standby internal power signal Pstb to a specified portion of the configurations of the memory device 1100 of FIG. 20 in the standby mode. For example, the internal power generating circuit 100 may supply the standby internal power signal Pstb to the control logic 1160 and the input/output circuit 1140 to receive input/output signals 10 and control signals CTRL from the memory controller 1200 of FIG. 1 in the standby mode. The internal power generating circuit 100 may not supply the standby internal power signal Pstb to the remaining internal circuits (for example, the memory cell array 1110, the address decoder 1120, the page buffer circuit 1130, and the word line voltage generator 1150).

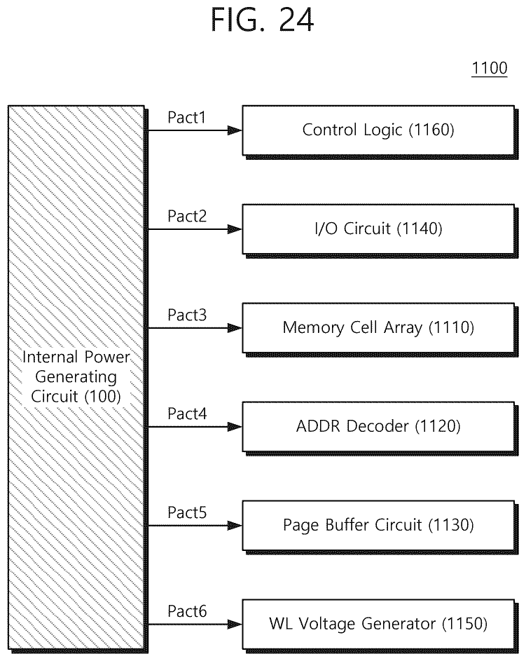

FIG. 24 is a diagram illustrating internal power supplied to components of the memory device during an active mode. Referring to FIG. 24, the internal power generating circuit 100 may generate a plurality of active internal power signals (Pact1 to Pact6) through a plurality of active reference circuits (for example, the first active reference circuit 131 and the second active reference circuit 132 of FIG. 3). The plurality of active internal power signals Pact1 to Pact6 may be set to different voltage levels. Or a portion of the active internal power signals Pact1 to Pact6 may be set to the same voltage level.

For example, the first active internal power signal Pact1 may be supplied to the control logic 1160. The second active internal power signal Pact2 may be supplied to the input/output circuit 1140. The third active internal power signal Pact3 may be supplied to the memory cell array 1110. The fourth active internal power signal Pact4 may be supplied to the address decoder 1120. The fifth active internal power signal Pact5 may be supplied to the page buffer circuit 1130. The sixth active internal power supply Pact6 may be supplied to the wordline voltage generator 1150.

According to the present disclosure, it may be possible to reduce standby power consumed during a standby mode, and it may be possible to individually or independently control internal power supplied to internal circuits during an active mode.

While the present disclosure has been described with reference to embodiments thereof, it will be apparent to those of ordinary skill in the art that various changes and modifications may be made thereto without departing from the spirit and scope of the present disclosure as set forth in the following claims.

1. An integrated circuit memory device, comprising:
a plurality of internal circuits; and
an internal power generating circuit electrically coupled to the plurality of internal circuits, and configured to:
generate a standby reference voltage based on an external supply power signal, and supply a standby internal power signal generated in response to the standby reference voltage to the plurality of internal circuits during a standby mode, and
generate a plurality of active reference voltages based on the external supply power signal, and supply each of a plurality of active internal power signals generated in response to respective ones of the plurality of active reference voltages to corresponding ones of the plurality of internal circuits during an active mode.

2. The device of claim 1, wherein the internal power generating circuit comprises a bandgap voltage reference circuit configured to generate a bandgap reference voltage having a magnitude that is within a specified range and independent of changes in the external supply power signal within an operating range.

3. The device of claim 2, wherein the internal power generating circuit comprises:
a standby reference circuit configured to generate the standby reference voltage based on the bandgap reference voltage; and
a plurality of standby drivers, which correspond to each of the plurality of internal circuits, and are configured to output a plurality of standby internal power signals set identically to the internal standby voltage based on the standby reference voltage.

4. The device of claim 3, wherein the plurality of standby internal power signals are configured to be supplied to the plurality of internal circuits regardless of the standby mode or the active mode, or be supplied to the plurality of internal circuits only in the standby mode.

5. The device of claim 2, wherein the internal power generating circuit comprises:
a plurality of active reference circuits configured to generate a plurality of active reference voltages based on the bandgap reference voltage in the active mode; and
a plurality of active drivers, which correspond to each of the plurality of internal circuits, and are configured to output a plurality of active internal power signals set to a plurality of internal active voltages based on the plurality of active reference voltages in the active mode.

6. A memory device, comprising:
a first internal circuit;
a second internal circuit; and
an internal power generating circuit configured to supply a first internal power to the first internal circuit based on an external supply power and supply a second internal power to the second internal circuit, and
wherein the internal power generating circuit is configured to:
during a standby mode, generate one standby reference voltage based on the external supply power, and supply the first internal power and the second internal power, which are commonly set on the standby reference voltage, to the first internal circuit and the second internal circuit, and
during an active mode, generate a first active reference voltage and a second active reference voltage based on the external supply power, and supply the first internal power set on the first active reference voltage to the first internal circuit, and supply the second internal power set on the second active reference voltage to the second internal circuit.

7. The memory device of claim 6, wherein the internal power generating circuit comprises a bandgap voltage reference circuit configured to generate a bandgap reference voltage within a specified range regardless of changes in surrounding environment based on the external supply power.

8. The memory device of claim 7, wherein the internal power generating circuit comprises:
a standby reference circuit configured to generate a standby reference voltage based on the bandgap reference voltage;
a first standby driver configured to supply the first internal power set to a first internal standby voltage based on the standby reference voltage to the first internal circuit in the standby mode; and
a second standby driver configured to supply the second internal power set to a second internal standby voltage based on the standby reference voltage to the second internal circuit in the standby mode.

9. The memory device of claim 8, wherein the first internal standby voltage and the second internal standby voltage is configured to be set to have the same voltage level as the standby reference voltage.

10. The memory device of claim 8, wherein the internal power generating circuit further comprises a bandgap reference switch configured to transmit the bandgap reference voltage to the standby reference circuit based on a standby enable signal and block the bandgap reference voltage based on an active enable signal.

11. The memory device of claim 10, further comprising:
control logic configured to output the standby enable signal when receiving a standby command from a memory controller and output the active enable signal when receiving an active command from the memory controller.

12. The memory device of claim 8, wherein the standby reference circuit is configured to be activated based on the standby enable signal in standby mode and deactivated based on the active enable signal in active mode.

13. The memory device of claim 7, wherein the internal power generating circuit comprises:
a first active reference circuit configured to generate a first active reference voltage based on the bandgap reference voltage in the active mode;
a second active reference circuit configured to generate a second active reference voltage based on the bandgap reference voltage;
a first active driver configured to supply a first internal power set on a first internal active voltage based on the first active reference voltage to the first internal circuit; and
a second active driver configured to supply a second internal power set on a second internal active voltage based on the second active reference voltage to the second internal circuit.

14. The memory device of claim 13, wherein the first active reference voltage is configured to be set to be the same as or different from the second active reference voltage.

15. The memory device of claim 13, wherein the first internal active voltage is configured to be set to be the same as or different from the second internal active voltage.

16. The memory device of claim 13, wherein the internal power generating circuit further comprises a bandgap reference switch configured to block the bandgap reference voltage based on a standby enable signal and commonly transmit the bandgap reference voltage to the first active reference circuit and the second active reference circuit based on an active enable signal.

17. The memory device of claim 13, wherein the first active reference circuit and the second active reference circuit is configured to be deactivated based on a standby enable signal or activated based on an active enable signal.

18. A memory device, comprising:
a first internal circuit;
a second internal circuit; and
an internal power generating circuit configured to supply a first internal power to the first internal circuit based on an external supply power and supply a second internal power to the second internal circuit,
wherein the internal power generating circuit comprises:
a main reference circuit configured to generate one standby reference voltage based on a standby enable signal and generate a plurality of active reference voltages based on an active enable signal;
a standby driver configured to generate an internal standby voltage based on the standby reference voltage and supply the internal standby voltage to the first internal circuit and the second internal circuit during a standby mode;
a first active driver configured to generate a first internal active voltage based on a first active reference voltage among the plurality of active reference voltages and supply the first internal active voltage to the first internal circuit during an active mode; and
a second active driver configured to generate a second internal active voltage based on a second active reference voltage among the plurality of active reference voltages and supply the second internal active voltage to the second internal circuit in the active mode.

19. The memory device of claim 18, further comprising:
control logic configured to output the standby enable signal when receiving a standby command from a memory controller and output the active enable signal when receiving an active command from the memory controller.

20. The memory device of claim 18, wherein the standby driver is configured to generate the internal standby voltage based on the standby reference voltage in the active mode, and
wherein the internal power generating circuit is configured to supply the internal standby voltage and the first internal active voltage to the first internal circuit as the first internal power, and supply the internal standby voltage and the second internal active voltage to the second internal circuit as the second internal power.

21.-25. (canceled)
